(19) United States
(12) Patent Application Publication
(10) Pub. No.: US 2021/0050240 A1
(43) Pub. Date: Feb. 18, 2021

(54) TRANSFER METHOD AND TRANSFER APPARATUS FOR SUBSTRATE PROCESSING SYSTEM

(71) Applicant: Tokyo Electron Limited, Tokyo (JP)

(72) Inventors: Kazuki MOYAMA, Miyagi (JP); Kazuya NAGASEKI, Miyagi (JP)

(73) Assignee: Tokyo Electron Limited, Tokyo (JP)

(21) Appl. No.: 16/942,926

(22) Filed: Jul. 30, 2020

(30) Foreign Application Priority Data
Aug. 13, 2019 (JP) 2019-148490

(51) Int. Cl. H01L 21/677; H01L 21/67; H01L 21/683; H01L 21/687

(52) U.S. Cl. CPC H01L 21/67742; H01L 21/67748; H01L 21/68742; H01L 21/6838; H01L 21/67259

(57) ABSTRACT

A semiconductor substrate is transferred accurately with respect to an edge ring. A transfer apparatus uses a transfer method for a substrate processing system, where the method includes tray loading, measuring, positioning, substrate placement, and tray removing. The tray loading includes loading a tray on which a semiconductor substrate and an edge ring are placeable into a mounting chamber including a support. The measurement includes measuring a position of the edge ring placed on the tray and obtaining position information about the edge ring. The positioning includes positioning the semiconductor substrate based on the position information. The substrate placement includes placing the positioned semiconductor substrate onto the tray. The tray removing includes removing the tray on which the semiconductor substrate and the edge ring are placed from the mounting chamber.

### CROSS-REFERENCE TO RELATED APPLICATION

This application claims priority to Japanese Patent Application No. 2019-148490 filed on Aug. 13, 2019, the entire disclosure of which is incorporated herein by reference.

### TECHNICAL FIELD

The present disclosure relates to a transfer method and transfer apparatus for a substrate processing system.

### BACKGROUND

In plasma processing for semiconductor substrates, an edge ring (also called a focus ring) may be used along the periphery of a semiconductor substrate placed inside a process chamber (process module) having a predetermined degree of vacuum. With the edge ring controlling plasma around the substrate periphery, the semiconductor substrate can be processed uniformly across its peripheral and central portions. For this process, the semiconductor substrate and the edge ring are to be aligned properly with each other. The semiconductor substrate is thus to be transferred accurately with respect to the edge ring.

The edge ring can become worn through plasma processing and thus should be replaced regularly. In one approach to replacing the edge ring, the process chamber accommodating the edge ring is vented to the atmosphere. In another approach that does not require venting, an edge-ring storage space that is connected to a vacuum transfer chamber may be used for transferring the edge ring into the process chamber using a transfer mechanism included in the vacuum transfer chamber.

Yet, another method is to place a semiconductor substrate onto a tray and transfer the tray with the semiconductor substrate into the process chamber.

### BRIEF SUMMARY

A semiconductor substrate typically passes through an atmospheric transfer chamber, a loadlock chamber, and a vacuum transfer chamber before being transferred into a process chamber. Although the transfer mechanism is controlled to transfer the semiconductor substrate accurately with respect to an edge ring placed inside the process chamber, the present inventors recognized a possible problem of the semiconductor substrate being initially improperly placed with respect to the transfer mechanism before being transferred into the process chamber, and so the semiconductor substrate may not to be transferred accurately. Further, the present inventors recognized that when the transfer mechanism in the vacuum transfer chamber is used to transfer an edge ring into the process chamber, the edge ring is also to be transferred and placed accurately onto a support for the edge ring.

The present disclosure is directed to a technique for placing a semiconductor substrate accurately with respect to an edge ring.

A transfer method for a substrate processing system according to one aspect of the present disclosure includes tray loading, measurement, positioning, substrate placement, and tray removing. The tray loading includes loading a tray on which a semiconductor substrate and an edge ring are placeable into a mounting chamber that includes a support. The measurement includes measuring a position of the edge ring placed on the tray and obtaining position information about the edge ring. The positioning includes positioning the semiconductor substrate based on the position information. The substrate placement includes placing the semiconductor substrate onto the tray, after the semiconductor substrate was positioned based on the position information. The tray removing includes removing the tray on which the semiconductor substrate and the edge ring are placed from the mounting chamber.

This exemplary technique according to the present disclosure allows accurate placement of a semiconductor substrate with respect to an edge ring.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings.

FIG. 1 is a diagram of a substrate processing system with its exemplary structure.

FIG. 2 is a diagram of a process module with its exemplary structure.

FIG. 3 is a plan view and cross-sectional diagram of a tray showing its example shape.

FIG. 4 is a plan view and cross-sectional diagram of an edge ring placed on the tray, showing its example shape.

FIG. 5 is a plan view and cross-sectional diagram of an edge ring and a wafer (or semiconductor substrate) placed on the tray, showing their example shapes.

FIG. 6 is a diagram of a mounting apparatus according to an embodiment.

FIG. 7 is a flowchart of an example transfer method according to an embodiment.

FIG. 8 is a diagram of the mounting apparatus during a step in the example transfer method.

FIG. 9 is a diagram of the mounting apparatus during another step in the example transfer method.

FIG. 10 is a diagram of the mounting apparatus during another step in the example transfer method.

FIG. 11 is a diagram of the mounting apparatus during another step in the example transfer method.

FIG. 12 is a graph of a relationship between a capacitance per unit area and an attractive force per unit area generated in an electrostatic chuck (ESC) in a process module according to an embodiment.

FIG. 13 is a diagram showing the arrangement of a rotation angle sensor and horizontal position sensors.

FIG. 14 is a diagram of an edge ring and a wafer that are accurately aligned with each other.

FIG. 15 is a diagram illustrating an example of positioning of a wafer.

FIG. 16 is another diagram illustrating an example of positioning of a wafer.

FIG. 17 is another diagram illustrating an example of positioning of a wafer.

FIG. 18 is another diagram illustrating an example of positioning of a wafer.

FIG. 19 is a diagram of a substrate processing system, according to an embodiment, with a tray storage connected to a vacuum transfer chamber.

FIG. 20 is a diagram of an example tray having an edge-ring support flush with a substrate support.

FIG. 21 is a diagram of a mounting apparatus with application of a direct-current (DC) voltage applied to a tray body without using a lift pin.

FIG. 22 is another diagram of a mounting apparatus with application of a direct-current (DC) voltage applied to a tray body without using a lift pin.

FIG. 23 is a diagram of a mounting apparatus with application of a direct-current (DC) voltage applied to a tray body without using a lift pin.

FIG. 24 is another diagram of an exemplary mounting apparatus that removes static electricity from a wafer W without using a lift pin.

FIG. 25 is another diagram of an exemplary mounting apparatus that removes static electricity from a wafer W without using a lift pin.

FIG. 26 is a diagram of an example tray serving as a bipolar electrostatic chuck (ESC).

FIG. 27 is a diagram of another exemplary mounting apparatus according to an embodiment.

FIG. 28 illustrates exemplary processing circuitry that performs computer-based operations in accordance with the present disclosure.

### DETAILED DESCRIPTION OF THE DRAWINGS

The description set forth below in connection with the appended drawings is intended as a description of various embodiments of the disclosed subject matter and is not necessarily intended to represent the only embodiment(s). In certain instances, the description includes specific details for the purpose of providing an understanding of the disclosed subject matter. However, it will be apparent to those skilled in the art that embodiments may be practiced without these specific details. In some instances, well-known structures and components may be shown in block diagram form in order to avoid obscuring the concepts of the disclosed subject matter.

Reference throughout the specification to “one embodiment” or “an embodiment” means that a particular feature, structure, characteristic, operation, or function described in connection with an embodiment is included in at least one embodiment of the disclosed subject matter. Thus, any appearance of the phrases “in one embodiment” or “in an embodiment” in the specification is not necessarily referring to the same embodiment. Further, the particular features, structures, characteristics, operations, or functions may be combined in any suitable manner in one or more embodiments. Further, it is intended that embodiments of the disclosed subject matter can and do cover modifications and variations of the described embodiments.

It must be noted that, as used in the specification and the appended claims, the singular forms “a,” “an,” and “the” include plural referents unless the context clearly dictates otherwise. That is, unless clearly specified otherwise, as used herein the words “a” and “an” and the like carry the meaning of “one or more.” Additionally, it is to be understood that terms such as “left,” “right,” “top,” “bottom,” “front,” “rear,” “side,” “height,” “length,” “width,” “upper,” “lower,” “interior,” “exterior,” “inner,” “outer,” and the like that may be used herein, merely describe points of reference and do not necessarily limit embodiments of the disclosed subject matter to any particular orientation or configuration. Furthermore, terms such as “first,” “second,” “third,” etc., merely identify one of a number of portions, components, points of reference, operations and/or functions as described herein, and likewise do not necessarily limit embodiments of the disclosed subject matter to any particular configuration or orientation.

Embodiments of the present disclosure will now be described with reference to the drawings. In the embodiments described below, similar components are indicated by like reference numerals and will not be described repeatedly. The embodiments are illustrated by way of example and not by way of limitation in the accompanying drawings that are not to scale unless otherwise indicated.

### Structure of Substrate Processing System

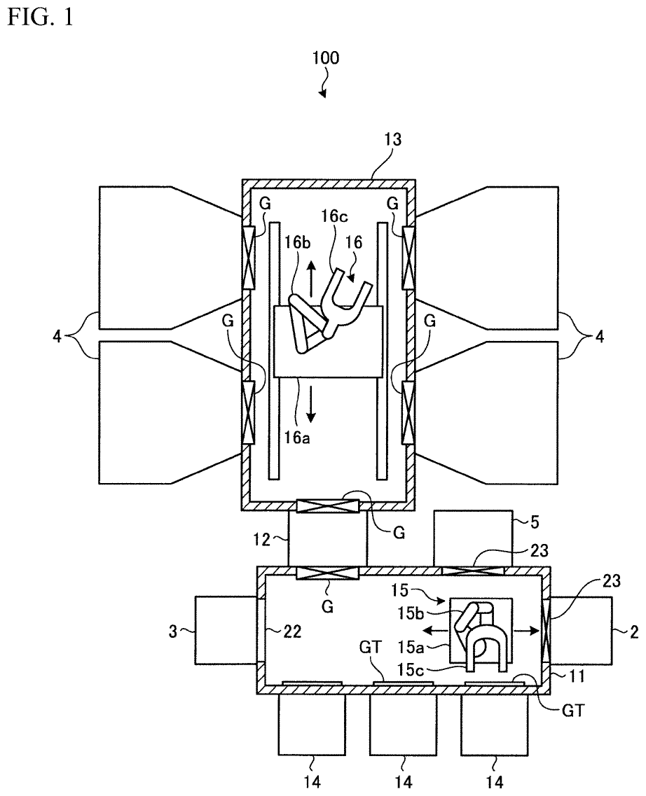

FIG. 1 is a diagram of a substrate processing system showing its example structure. In FIG. 1, a substrate processing system 100 includes front-opening unified pods (FOUPs) 14, an atmospheric transfer chamber 11, an edge-ring storage facility 2, a tray storage facility 5, an aligner 3, a loadlock chamber 12, a vacuum transfer chamber 13, process modules 4, a first transfer mechanism 15, and a second transfer mechanism 16. While the term “mechanism” is used for convenience as a label, the transfer mechanisms are circuitry controlled assemblies that have controllable, movable arms, which are controlled to move items from one space to another. Thus, the transfer mechanism may also be referred to as transfer assembly/assemblies.

Each FOUP 14 is an enclosure for storing semiconductor substrates (hereinafter also referred to as wafers) and has a lid to open and close the enclosure. When a FOUP 14 that is storing wafers is attached to the atmospheric transfer chamber 11, the lid of the FOUP 14 is engaged with a gate door GT of the atmospheric transfer chamber 11 and is unlatched. The lid of the FOUP 14 can be open in this state. When the gate door GT is open in this state, the lid of the FOUP 14 moves together with the gate door GT and is open, thus connecting the inside of the FOUP 14 with the inside of the atmospheric transfer chamber 11.

The atmospheric transfer chamber 11 maintains an ambient atmosphere inside. The edge-ring storage facility 2 and the tray storage facility 5 are connected to the atmospheric transfer chamber 11 via shutters 23, which can be open and closed. The edge-ring storage facility 2 stores multiple edge rings. The tray storage facility 5 stores multiple trays. The aligner 3 is also connected to the atmospheric transfer chamber 11 through an opening 22. The atmospheric transfer chamber 11 accommodates the first transfer mechanism 15, which transfers and receives wafers, edge rings, and trays to and from the FOUPs 14, the edge-ring storage facility 2, the tray storage facility 5, the aligner 3, and the loadlock chamber 12. The first transfer mechanism 15 includes a base 15a, an articulated arm 15b, and a pick 15c. The arm 15b has a basal end connected to the base 15a and a distal end connected to the pick 15c. The base 15a is movable in directions indicated by the arrows (along the length of the atmospheric transfer chamber 11) in the atmospheric transfer chamber 11. The pick 15c is U-shaped to support a wafer, an edge ring, and a tray. When the pick 15c retrieves an edge ring from the edge-ring storage facility 2, the shutter 23 between the edge-ring storage facility 2 and the atmospheric transfer chamber 11 is open. When the pick 15c retrieves a tray from the tray storage facility 5, the shutter 23 between the tray storage facility 5 and the atmospheric transfer chamber 11 is open.

The atmospheric transfer chamber 11 and the vacuum transfer chamber 13 are connected via the loadlock chamber 12. The vacuum transfer chamber 13 maintains a vacuum atmosphere inside. The loadlock chamber 12 is separated from the atmospheric transfer chamber 11 and from the vacuum transfer chamber 13 by gate valves G. The gate valves G are normally closed. When the first transfer mechanism 15 transfers a wafer, an edge ring, or a tray from the atmospheric transfer chamber 11 into the loadlock chamber 12, the gate valve G between the atmospheric transfer chamber 11 and the loadlock chamber 12 is open. When the second transfer mechanism 16 unloads a tray supporting an edge ring and a wafer from the loadlock chamber 12 and loads the tray into the vacuum transfer chamber 13, the gate valve G between the loadlock chamber 12 and the vacuum transfer chamber 13 is open. The first transfer mechanism 15 is controlled with circuit logic which may be hardwired (e.g., application specific integrated circuit, ASIC) and/or a computer processor that is software programmable. The circuit logic controls the actuation of motors that control the movement of the transfer mechanism according to software routines that are either autonomous (e.g., recipe) and/or responsive to external input such as by an operator who inputs commands via a user interface to the transfer mechanism 15. The circuit logic may use a computer, and/or microprocessor(s) as will be discussed later.

The loadlock chamber 12 is connected to a vacuum pump (not shown) serving as an exhaust mechanism and a leak valve (not shown) for restoring the atmospheric pressure in the chamber. The inside of the loadlock chamber 12 is thus switchable between the ambient atmosphere and the vacuum atmosphere. When the first transfer mechanism 15 transfers a wafer, an edge ring, or a tray from the atmospheric transfer chamber 11 into the loadlock chamber 12, the inside of the loadlock chamber 12 is switched to the ambient atmosphere. When the second transfer mechanism 16 unloads a tray supporting a wafer and an edge ring from the loadlock chamber 12 and loads the tray into the vacuum transfer chamber 13, the inside of the loadlock chamber 12 is switched to the vacuum atmosphere.

The second transfer mechanism 16 in the vacuum transfer chamber 13 transfers and receives a tray supporting a wafer and an edge ring between the loadlock chamber 12 and one of the process modules 4. The second transfer mechanism 16 includes a base 16a, an articulated arm 16b, and a pick 16c. The arm 16b has a basal end connected to the base 16a and a distal end connected to the pick 16c. The base 16a is movable in directions indicated by the arrows (along the length of the vacuum transfer chamber 13) in the vacuum transfer chamber 13. The pick 16c is U-shaped to support a tray supporting a wafer and an edge ring. The second transfer mechanism 16 has a similar circuit-based controller as discussed with respect to the first transfer mechanism 15.

The vacuum transfer chamber 13 is separated from the process modules 4 with the gate valves G. The gate valves G are normally closed. When the second transfer mechanism 16 transfers a tray supporting a wafer and an edge ring from the vacuum transfer chamber 13 into one of the process modules 4, the gate valve G between the vacuum transfer chamber 13 and the process module 4 is open.

The process modules 4 each process a wafer as a workpiece in the vacuum atmosphere. The process modules 4 perform processing such as etching or film deposition on a wafer placed on a tray.

### Structure of Process Module

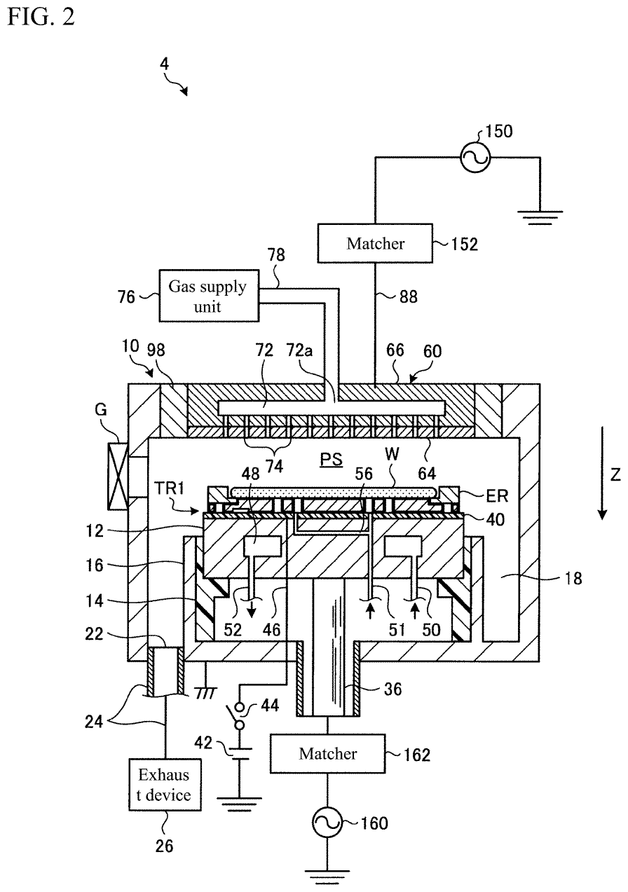

FIG. 2 is a diagram of an exemplary process module 4, which in this example is a capacitively coupled plasma apparatus. The process module 4 includes a process chamber 10 formed from a metal such as aluminum or stainless steel. The process chamber 10 is electrically grounded for protection.

The process chamber 10 accommodates a disk-shaped susceptor 12 that is generally horizontally oriented, such that a top surface is horizontal in the process chamber 10. A tray TR1 supporting a wafer W and an edge ring ER is placed onto the susceptor 12. The susceptor 12 also serves as a lower electrode. The process chamber 10 has the gate valve G on the side wall for opening and closing the port to load and unload the tray TR1. The susceptor 12 is formed from, for example, a metal such as aluminum and is supported on an insulating cylindrical support 14 that extends vertically upward from the bottom of the process chamber 10.

A conductive cylindrical support (inner wall) 16, which surrounds the outer periphery of the cylindrical support 14, extends vertically upward from the bottom of the process chamber 10. The cylindrical support 16 and the side wall of the process chamber 10 together define an annular exhaust path 18. The exhaust path 18 has an outlet 22 on its bottom.

The outlet 22 is connected to an exhaust device 26 through an exhaust pipe 24. The exhaust device 26 includes a vacuum pump, such as a turbomolecular pump, to reduce the pressure in a process space PS in the process chamber 10 to an intended degree of vacuum. The process chamber 10 may maintain a pressure of, for example, 10 to 3,500 mTorr inside.

The wafer W as a processing target substrate is placed onto the tray TR1 on the susceptor 12, with the edge ring ER placed along the periphery of the wafer W. The edge ring ER is formed from either a conductive material such as Si or SiC or an insulating material such as SiO₂. The edge ring ER is placed on the upper surface of the tray TR1.

An electrostatic chuck (ESC) 40 for attracting a wafer is located on the upper surface of the susceptor 12. The ESC 40 includes a sheet or mesh conductor between dielectric films or plates. The conductor in the ESC 40 is coupled to a direct-current (DC) power supply 42 located outside the process chamber 10 via a switch 44 and a power supply line 46. With the switch 44 turned on, the DC power supply 42 applies a DC voltage to the ESC 40 to generate a Coulomb force in the ESC 40, causing the ESC 40 to electrostatically attract the wafer W through the tray TR1.

The susceptor 12 has an annular refrigerant compartment 48 extending circumferentially inside. The refrigerant compartment 48 contains a refrigerant (e.g., cooling water) with a predetermined temperature that is circulated from a chiller unit (not shown) through pipes 50 and 52. The temperature of the refrigerant is controlled to control the temperature of the wafer W. To more precisely control the temperature of the wafer W, a heat-transfer gas supply unit (not shown) supplies a heat-transfer gas (e.g., He gas) between the tray TR1 and the wafer W through a gas supply line 51 and a gas flow channel 56 in the susceptor 12.

A disk-shaped upper electrode 60 is located on the ceiling of the process chamber 10 parallel to and facing (or opposite to) the susceptor 12. The upper electrode 60 is attached to the ceiling of the process chamber 10 with a ring-shaped insulator 98 formed from, for example, ceramics.

The upper electrode 60 includes an electrode plate 64 directly facing the susceptor 12 and an electrode support 66 supporting the electrode plate 64 from behind (or from above) in a detachable manner. The electrode plate 64 may be formed from a conductive material, such as Si or Al. The electrode support 66 is formed from, for example, anodized aluminum. Moreover, the Si may be doped to enhance its conductivity, or formed as doped polysilicon. As described above, the process module 4 includes the disk-shaped susceptor 12 (lower electrode) and the disk-shaped upper electrode 60 located parallel to and facing each other.

A gas supply unit 76 supplies a process gas to the process chamber 10. The upper electrode 60 also serves as a shower head electrode for supplying the process gas into the process space PS defined between the upper electrode 60 and the susceptor 12. In more detail, the electrode support 66 includes a gas diffusing compartment 72 connected to many gas outlets 74 extending toward the susceptor 12 through the electrode support 66 and the electrode plate 64. A gas inlet 72a located in an upper portion of the gas diffusing compartment 72 is connected to a gas supply line 78 extending from the gas supply unit 76.

The upper electrode 60 is coupled to a first radio frequency (RF) power supply 150 via a first impedance matching circuit, or “matcher” 152. The first matcher 152 performs impedance matching between the first RF power supply 150 and a load (mainly the electrode, plasma, and the process chamber). The first RF power supply 150 can apply an RF voltage for generating plasma with a frequency of 30 to 150 MHz to the upper electrode 60. Once the upper electrode 60 receives such a high RF voltage, it can generate well-dissociated and high-density plasma in the process space PS, thus enabling plasma processing under lower pressure conditions. The first RF power supply 150 may output a voltage with a frequency of 50 to 80 MHz, and be typically adjusted to output a voltage with 60 MHz or similar frequencies.

The susceptor 12 as the lower electrode is coupled to a second RF power supply 160 with a connection rod 36 via a second matcher 162. The second impedance matching circuit, or “matcher” 162 performs impedance matching between the second RF power supply 160 and a load (mainly the electrode, plasm, and the process chamber). The second RF power supply 160 can apply an RF voltage for biasing with a frequency of several hundred kilohertz to about ten to twenty megahertz to the susceptor 12. The second RF power supply 160 is typically adjusted to output a voltage with a frequency of, for example, 2 MHz or 13.56 MHz. Shapes of Tray, Edge Ring, and Wafer

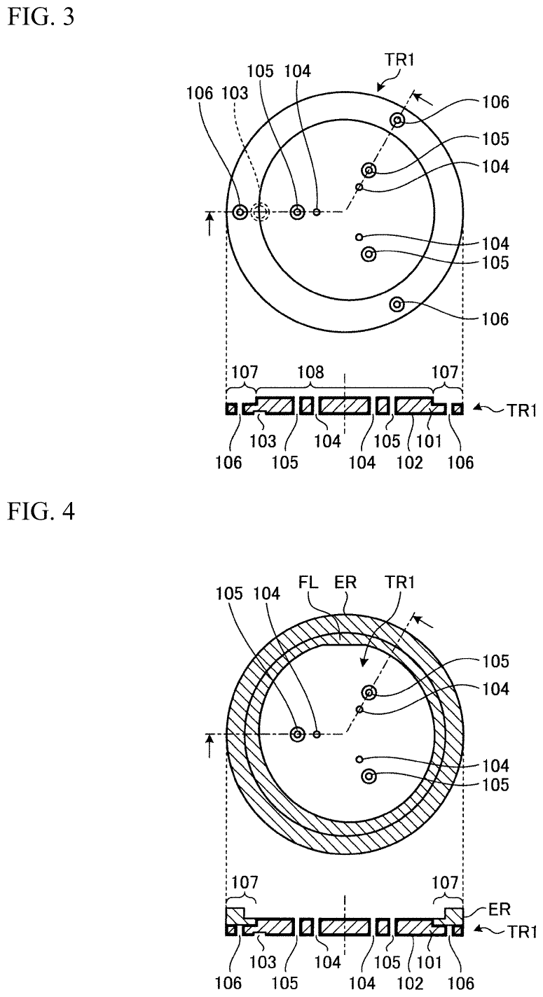

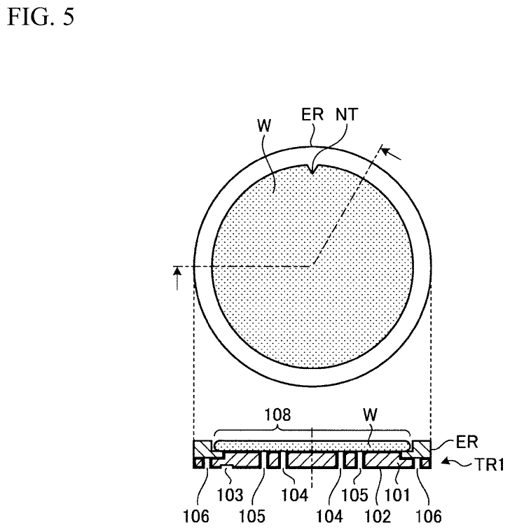

FIG. 3 is a diagram of a tray showing its example shape. FIG. 4 is a diagram of an edge ring placed on the tray, showing its example shape. FIG. 5 is a diagram of an edge ring and a wafer placed on the tray, showing their example shapes.

As shown in the plan view of FIG. 3, the tray TR1 is disk-shaped and includes a conductive tray body 101, a dielectric film 102 coating the tray body 101, a lift pin contact 103, and through-holes 104, 105, and 106. Through-holes 104 allow supply of a heat-transfer gas between the tray TR1 and the wafer W through the gas flow channel 56 (FIG. 2) in the process module 4. Through-holes 105 receive a lift pin for raising and lowering the wafer W. Through-holes 106 receive a lift pin for raising and lowering the edge ring ER. The lift pin contact 103 is a part of the back surface of the tray body 101 without the dielectric film 102 and can be in contact with the lift pin raising the tray TR1. The lift pin contact 103 may be recess-shaped to receive the lift pin. The tray TR1 includes a substrate support 108 on its upper surface for supporting the wafer W and an edge-ring support 107 for supporting the edge ring ER. The edge-ring support 107 surrounds the substrate support 108. More specifically, the substrate support 108 and the edge-ring support 107 are parts of the conductive tray body 101 and include the dielectric film 102 coating the tray body 101. The edge-ring support 107 is located lower than the substrate support 108. The dielectric film 102 may be located on at least the upper surface of the tray body 101.

As shown in the plan view portion of FIG. 4, the edge ring ER is annular and has a circular outer peripheral portion and a partially flat inner peripheral portion with a flat FL. The edge ring ER is placed onto the edge-ring support 107 that is on the upper surface of the tray TR1. The edge ring ER has the inner peripheral portion thinner than the outer peripheral portion. More specifically, the edge ring ER placed on the edge-ring support 107 has the inner peripheral portion with the upper surface substantially flush with or lower than the upper surface of the substrate support 108. The edge ring ER also has the outer peripheral portion with the upper surface substantially flush with or higher than the upper surface of the wafer W placed on the substrate support 108 that is on the upper surface of the tray TR1.

As shown in the plan view portion of FIG. 5, the wafer W is disk-shaped and has a V-shaped notch NT on its outer periphery. The wafer W is placed onto the substrate support 108 that is on the upper surface of the tray TR1. The wafer W is placed onto the substrate support 108 to have the notch NT at the flat FL on the edge ring ER. As described above, the substrate support 108 has a support surface supporting the back surface of the wafer W and the through-holes 104 and 105 extending through the tray body 101 and the dielectric film 102. The substrate support 108 has a smaller surface area than the wafer W. More specifically, the wafer W is placed onto the substrate support 108 to have the outer peripheral portion with the notch NT located outside the outer periphery of the substrate support 108 and on the inner peripheral portion of the edge ring ER.

As described above, the wafer W and the edge ring ER can be placed onto the tray TR1.

### Structure of Mounting Apparatus

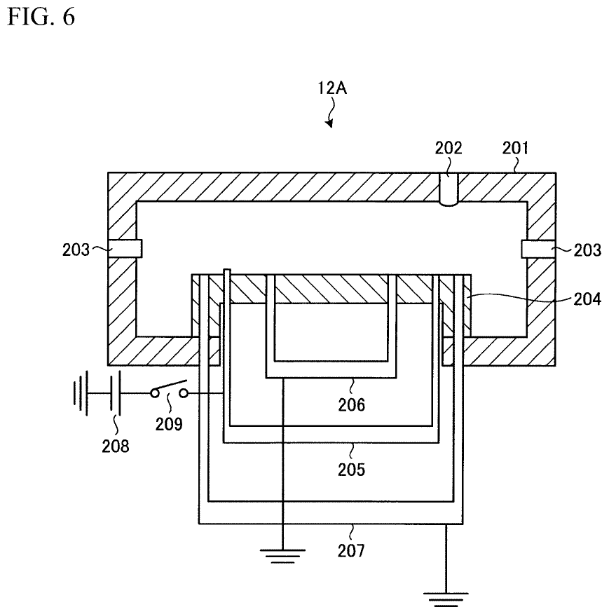

FIG. 6 is a diagram of a structure of an exemplary mounting apparatus 12A. In the present embodiment, the mounting apparatus 12A shown in FIG. 6 serves as the loadlock chamber 12 (see FIG. 1). In FIG. 6, the mounting apparatus 12A includes a chamber 201, a rotation angle sensor 202 (e.g., an optical sensor), horizontal position sensors 203 (e.g., also an optical sensor), a support 204, a first lift pin 205, a second lift pin 206, a third lift pin 207, a DC power supply 208, and a switch 209. The rotation angle sensor 202 is located on (or through) the upper wall of the chamber 201, and the horizontal position sensors 203 are located on (or through) the side walls of the chamber 201. The conductive chamber 201 accommodates the support 204. The mounting apparatus 12A includes a first lift mechanism (not shown, but one example is computer controller servo motor(s)) for raising and lowering the first lift pin 205, a second lift mechanism (not shown, but also one or more servo motors in this embodiment) for raising and lowering the second lift pin 206 independently of the first lift pin 205, and a third lift mechanism (not shown, but also one or more servo motors in this embodiment) for raising and lowering the third lift pin 207 independently of the first lift pin 205 and the second lift pin 206. Each lift mechanism may include an actuator, a motor, and/or another device that controllably urges the lift pin upward and downward. The first lift pin 205, the second lift pin 206, and the third lift pin 207 are formed from a conductive material (e.g., Ni or Al). The first lift pin 205 is coupled to the DC power supply 208 via the switch 209. The second lift pin 206 and the third lift pin 207 are grounded. The mounting apparatus 12A further includes a vacuum pump (not shown) serving as an exhaust mechanism that can reduce the pressure in the chamber 201 to a pressure lower than the atmospheric pressure, and a leak valve (not shown) for restoring the atmospheric pressure in the chamber 201.

### Transfer Method for Substrate Processing System

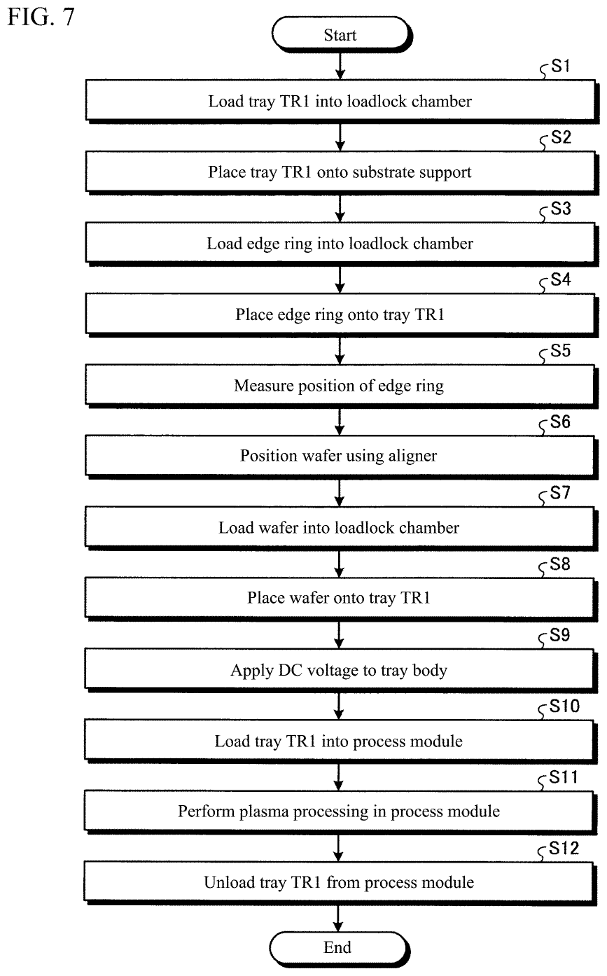

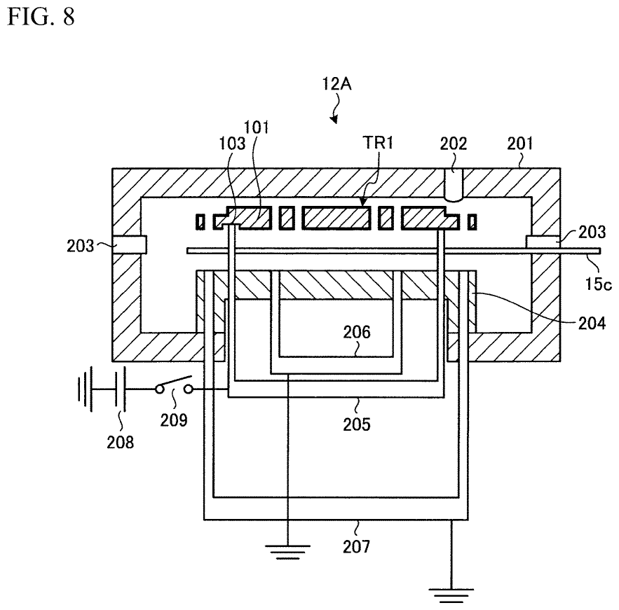

FIG. 7 is a flowchart showing an example procedure of a transfer method according to an embodiment. FIGS. 8 to 11 are diagrams of the mounting apparatus at various stages in the example transfer method.

In step S1, in FIG. 7, a tray TR1 is loaded into the loadlock chamber 12 using the first transfer mechanism 15. The tray TR1 is stored in the tray storage facility 5 connected to the atmospheric transfer chamber 11. The first transfer mechanism 15 unloads the tray TR1 from the tray storage facility 5 and loads the tray TR1 supported on the pick 15c into the loadlock chamber 12 (mounting apparatus 12A, as shown in FIG. 6 for example). The loadlock chamber 12 has an atmospheric pressure inside.

In step S2, the tray TR1 is then placed onto the support 204 in the loadlock chamber 12. As shown in FIG. 8, the first lift pin 205 is raised (in other words, the tray TR1 is lifted up) to separate the tray TR1 from the pick 15c, while coming in contact with the lift pin contact 103 on the back surface of the tray body 101.

With the first lift pin 205 held at the position shown in FIG. 8, the pick 15c is retracted from the loadlock chamber 12.

The first lift pin 205 is then lowered (in other words, the tray TR1 is moved down) to place the tray TR1 onto the support 204.

In step S3, an edge ring ER is loaded into the loadlock chamber 12 using the first transfer mechanism 15. The edge ring ER is stored in the edge-ring storage facility 2 connected to the atmospheric transfer chamber 11. The first transfer mechanism 15 unloads the edge ring ER from the edge-ring storage facility 2 and loads the edge ring ER supported on the pick 15c into the loadlock chamber 12.

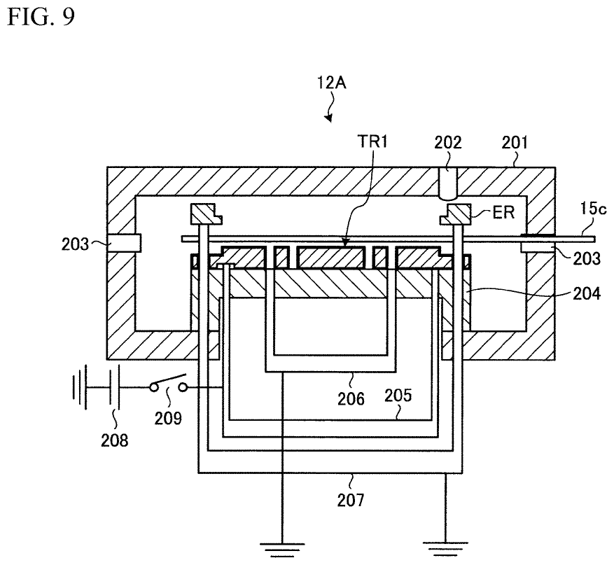

In step S4, the edge ring ER is placed onto the tray TR1, which itself is placed on the support 204 in the loadlock chamber 12. As shown in FIG. 9, the third lift pin 207 is raised (in other words, the edge ring ER is lifted up) to separate the edge ring ER from the pick 15c, while coming in contact with the back surface (underneath) of the edge ring ER through the through-holes 106 in the tray TR1. The third lift pin 207 is grounded and thus eliminates static electricity from the edge ring ER when its distal ends come in contact with the back surface of the edge ring ER.

With the third lift pin 207 held at the position shown in FIG. 9, the pick 15c is retracted from the loadlock chamber 12.

The third lift pin 207 is then lowered (in other words, the edge ring ER is moved down) to place the edge ring ER onto the tray TR1.

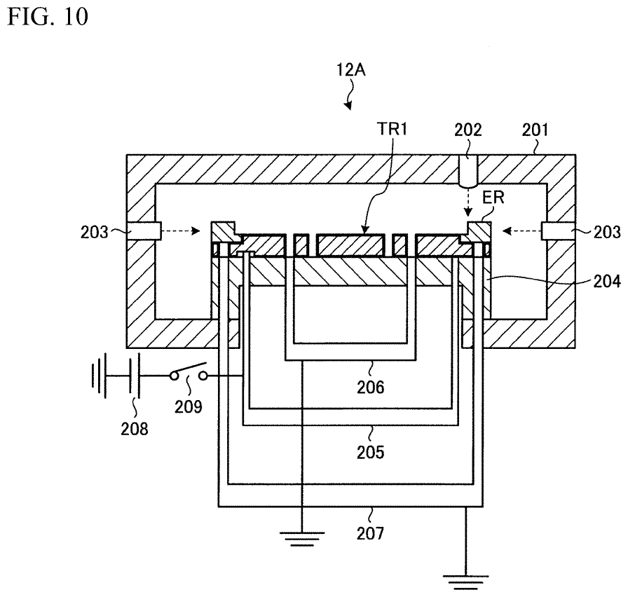

In step S5, the position of the edge ring ER placed on the tray TR1 is measured. As shown in FIG. 10, the position of the edge ring ER placed on the tray TR1 is measured using the rotation angle sensor 202 and the horizontal position sensors 203 to obtain position information about the edge ring ER. A signal representing the obtained position information is then transmitted to the aligner 3. The rotation angle sensor 202 includes, for example, a charge-coupled device (CCD) that optically detects the position of the ER. A rotation angle RA of the edge ring ER with respect to a predetermined reference position RP is measured using an image of the flat FL captured from above the edge ring ER. Rotation angle information RAI indicating the rotation angle RA is thus obtained as first position information about the edge ring ER. The horizontal position sensors 203 include, for example, lasers emitting light toward the edge ring ER from laterally outside the edge ring ER. A positional displacement HP of the edge ring ER in the horizontal direction with respect to the predetermined reference position RP is measured using a distance between each horizontal position sensor 203 and the outer periphery of the edge ring ER. Horizontal position information HPI indicating the positional displacement HP is thus obtained as second position information about the edge ring ER. The position information transmitted from the loadlock chamber 12 to the aligner 3 thus includes the rotation angle information RAI about the edge ring ER and the horizontal position information HPI about the edge ring ER.

In step S6, a wafer W is positioned using the aligner 3. The wafer W is transferred from the FOUP 14 into the aligner 3 using the first transfer mechanism 15. The aligner 3 positions the wafer W based on the position information transmitted from the loadlock chamber 12. More specifically, the aligner 3 rotates the wafer W based on the rotation angle information RAI about the edge ring ER and horizontally positions the wafer W based on the horizontal position information HPI about the edge ring ER. Positioning the wafer W will be described in detail later.

In step S7, the wafer W is loaded into the loadlock chamber 12 using the first transfer mechanism 15. The positioned wafer W is supported on the pick 15c in the first transfer mechanism 15, unloaded from the aligner 3, and transferred to above the support 204 in the loadlock chamber 12.

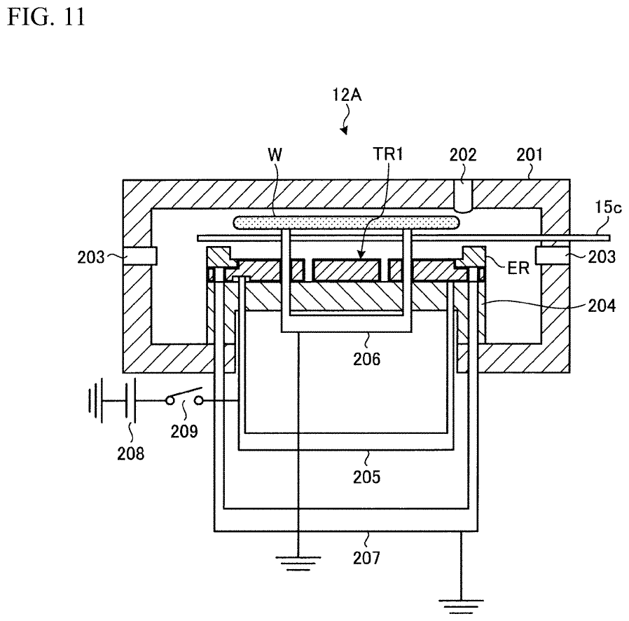

In step S8, the wafer W is then placed onto the tray TR1 placed on the support 204 in the loadlock chamber 12. As shown in FIG. 11, the second lift pin 206 is raised to separate the wafer W from the pick 15c (in other words, the wafer W is lifted up), while coming in contact with the back surface of the wafer W through the through-holes 105 in the tray TR1. The second lift pin 206 is grounded and thus eliminates static electricity from the wafer W when its distal ends come in contact with the back surface of the wafer W.

With the second lift pin 206 held at the position shown in FIG. 11, the pick 15c is retracted from the loadlock chamber 12.

The second lift pin 206 is then lowered (in other words, the wafer W is moved down) to place the wafer W onto the tray TR1.

In step S9, a DC voltage is applied to the tray body 101. The vacuum pump starts exhausting air from the chamber 201 to cause the first lift pin 205 to be in contact with the lift pin contact 103. The switch 209 is turned on to couple the first lift pin 205 to the DC power supply 208, allowing the DC power supply 208 to apply a positive DC voltage to the first lift pin 205. The first lift pin 205 receives a positive DC voltage from the DC power supply 208, which is then applied to the tray body 101 through the first lift pin 205 and the lift pin contact 103. The DC voltage applied to the tray body 101 generates a Coulomb force in the tray TR1, which then electrostatically attracts the wafer W. The edge ring ER formed from, for example, a conductive material such as Si or SiC, is also electrostatically attracted to the tray TR1. Moreover, the Si or SiC may be doped to enhance its conductivity, or formed as doped polysilicon. As described above, the wafer W is electrostatically attracted to the tray TR1 with the first lift pin 205 in contact with the back surface of the tray body 101 and with a DC voltage applied to the tray body 101 through the first lift pin 205.

In step S10, the tray TR1 supporting the edge ring ER and the wafer W is then loaded into the process module 4. The switch 209 is turned off to stop the DC voltage applied to the tray body 101, whereas the first lift pin 205 is raised with its distal ends remaining in contact with the back surface of the tray TR1. This allows the tray TR1 to remain charged after the DC voltage applied to the tray body 101 is stopped, allowing the wafer W to remain attracted to the tray TR1.

The tray TR1 is unloaded from the loadlock chamber 12 using the second transfer mechanism 16 in the vacuum transfer chamber 13. The pick 16c in the second transfer mechanism 16 is advanced into the loadlock chamber 12 and is located under the tray TR1, which is lifted by the first lift pin 205.

The first lift pin 205 is then lowered to place the tray TR1 onto the pick 16c. After retracting the pick 16c from the loadlock chamber 12, the second transfer mechanism 16 transfers the tray TR1 supporting the wafer W and the edge ring ER from the loadlock chamber 12 to the process module 4.

While being transferred from the loadlock chamber 12 into the process module 4, the tray TR1 supporting the wafer W and the edge ring ER remains charged, allowing the positioned wafer W to remain attracted to the tray TR1. The positioned wafer W can avoid displacement while being transferred from the loadlock chamber 12 into the process module 4.

The edge ring ER typically weighs more than the wafer W. The edge ring ER is thus less likely to be displaced than the wafer W when the tray TR1 is transferred from the loadlock chamber 12 into the process module 4. The edge ring ER is formed from an insulating material such as SiO₂ and is also effectively transferred using the tray TR1. The edge ring ER is formed from a conductive material such as Si or SiC and is attracted to the tray TR1 together with the wafer W, and thus can be transferred more effectively.

The tray TR1 transferred into the process module 4 is placed onto the susceptor 12 (ESC 40) in the process module 4. The susceptor 12 includes a lift pin (not shown). The tray TR1 is placed onto the susceptor 12 (ESC 40) in the same manner as in step S2. After the tray TR1 is placed onto the ESC 40, the switch 44 is turned on to cause the DC power supply 42 to apply a DC voltage to the ESC 40. The wafer W is attracted to the ESC 40 through the tray TR1.

In step S11, plasma processing, such as etching, is performed.

When the plasma processing is complete, the tray TR1 supporting the edge ring ER and the wafer W is unloaded from the process module 4 in step S12. The tray TR1 unloaded from the process module 4 is placed onto the support 204 in the loadlock chamber 12. After the atmospheric pressure in the loadlock chamber 12 is restored using the leak valve (not shown), the first transfer mechanism 15 unloads the wafer W from the loadlock chamber 12. The unloaded wafer W is stored into the FOUP 14.

The edge ring ER and the tray TR1 may or may not be stored separately in the edge-ring storage facility 2 and the tray storage facility 5. A new wafer W may be loaded into the loadlock chamber 12 while the edge ring ER and the tray TR1 remain on the support 204 in the loadlock chamber 12. In this case, the subsequent processing may be started from step S5 or step S6. To replace the edge ring ER that has worn, the edge ring ER may be stored into the edge-ring storage facility 2 and a new edge ring ER may be loaded into the loadlock chamber 12. In this case, the subsequent processing may be started from step S3.

### Attractive Force in ESC

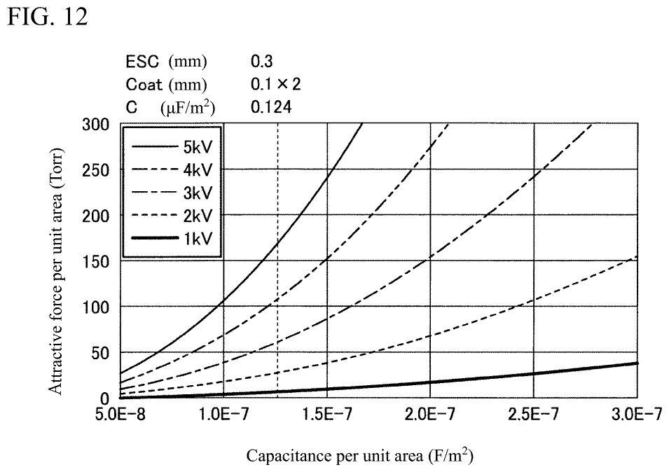

In step S10, the tray TR1 loaded into the process module 4 is placed onto the ESC 40. The wafer W is placed onto the tray TR1, instead of being placed directly onto the ESC 40. FIG. 12 is a graph showing the relationship between a capacitance per unit area and an attractive force per unit area generated in the ESC in the process module. For example, when a dielectric layer above an electrode incorporated in the ESC has a thickness of 0.3 mm, the dielectric films 102 on the upper and lower surfaces of the tray body 101 each have a thickness of 0.1 mm, and the dielectric materials have a relative dielectric constant of 8.5, the tray TR1 has a capacitance of 0.124 g/m². When the DC power supply 42 applies a DC voltage of 5 kV to the ESC 40, the ESC 40 generates a Coulomb force with an attractive force of about 170 Torr per unit area. The attractive force is large enough to attract the wafer W without being separated from the tray TR1 placed on the ESC 40 under the pressure applied from a heat-transfer gas supplied between the tray TR1 and the wafer W in the process module 4.

### Positioning Wafer

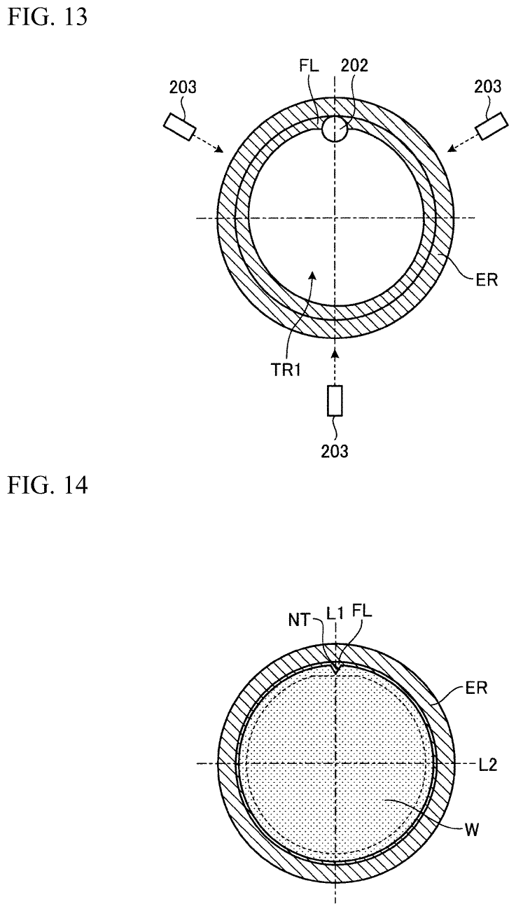

FIG. 13 is a diagram showing the arrangement of the rotation angle sensor and the horizontal position sensors. As shown in FIG. 13, the edge ring ER is placed onto the tray TR1 with the flat FL located under the rotation angle sensor 202 in the mounting apparatus 12A. The horizontal position sensors 203 are at three positions surrounding the edge ring ER placed on the tray TR1 in the mounting apparatus 12A.

FIG. 14 is a diagram of the edge ring and the wafer that are accurately aligned with each other. As shown in FIG. 14, when the edge ring ER and the wafer W are accurately aligned with each other, the edge ring ER is concentric with the wafer W, with the apex of the notch NT in the middle of the flat FL on the edge ring ER. To align the edge ring ER and the wafer W accurately with each other, a straight reference line L1 and a straight reference line L2 are preset. The reference position RP is defined by the reference line L1 in the lateral direction and the reference line L2 in the vertical direction. The reference lines L1 and L2 intersect perpendicularly with each other. When the edge ring ER and the wafer W are accurately aligned with each other, the centers of the edge ring ER and the wafer W align with the intersection between the reference lines L1 and L2 and the middle of the flat FL and the apex of the notch NT align with the reference line L1.

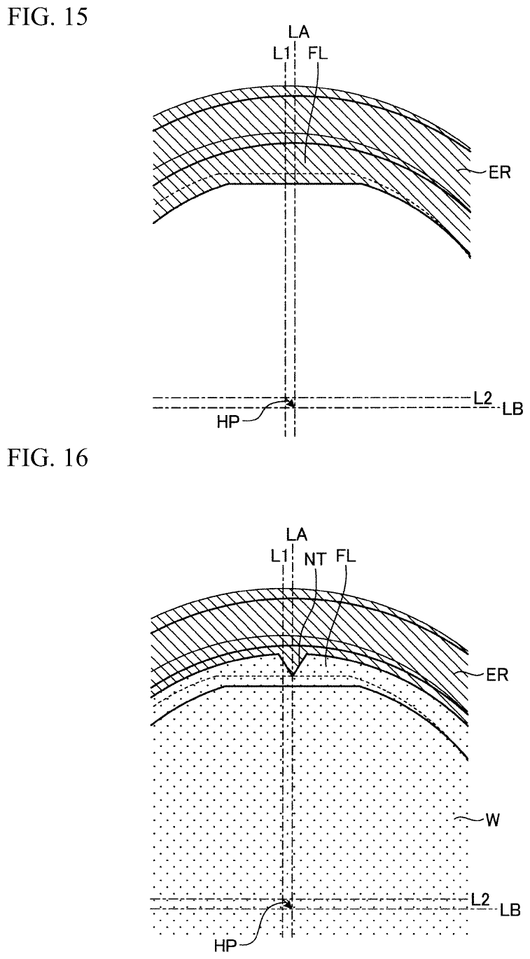

FIGS. 15 to 18 are diagrams each describing an example of positioning of the wafer. FIGS. 15 and 17 each show the position of the edge ring ER placed on the tray TR1, and FIGS. 16 and 18 each show the position of the positioned wafer W.

As shown in FIG. 15, a positional displacement HP of the edge ring ER placed on the tray TR1 in the horizontal direction with respect to the reference position RP, which is defined by the reference lines L1 and L2, is measured using the horizontal position sensors 203. To measure the positional displacement HP, a straight line LA in the lateral direction and a straight line LB in the vertical direction are defined for the edge ring ER placed on the tray TR1, as shown in FIG. 15. The straight line LA and the straight line LB intersect perpendicularly with each other. The center of the edge ring ER aligns with the intersection between the straight lines LA and LB, and the middle of the flat FL aligns with the straight line LA. The horizontal position sensors 203 measure, as a positional displacement HP, the direction and the degree of displacement of the intersection between the straight lines LA and LB from the intersection between the reference lines L1 and L2. To position the wafer W horizontally with the aligner 3, the center position of the wafer W is moved from the intersection between the reference lines L1 and L2 by the positional displacement HP as shown in FIG. 16. The wafer W is concentric with the edge ring ER, which is placed on the tray TR1 with the positional displacement HP. This provides a constant clearance between the inner periphery of the edge ring ER and the outer periphery of the wafer W inside the edge ring ER across the entire peripheries.

As shown in FIG. 17, a rotation angle RA of the edge ring ER placed on the tray TR1 with respect to the reference position RP, which is defined by the reference lines L1 and L2, is measured using the rotation angle sensor 202. To measure the rotation angle RA, a straight line LC in the lateral direction and a straight line LD in the vertical direction are defined for the edge ring ER placed on the tray TR1, as shown in FIG. 17. The straight line LC and the straight line LD intersect perpendicularly with each other. The center of the edge ring ER and the intersection between the reference lines L1 and L2 align with the intersection between the straight lines LC and LD, and the middle of the flat FL aligns with the straight line LC. The rotation angle sensor 202 measures the rotation angle RA of the straight line LC with respect to the reference line L1. To rotate the wafer W with the aligner 3, the wafer W is rotated from the reference position RP by the rotation angle RA. This allows the wafer W to be placed with the apex of the notch NT aligning with the middle of the flat FL on the edge ring ER placed on the tray TR1 with its flat FL displaced by the rotation angle RA, as shown in FIG. 18.

In the present embodiment, the edge ring ER and the wafer W are placed onto the tray TR1 in the loadlock chamber 12, and the tray TR1 is transferred into the process module 4. The position of the edge ring ER is then measured in the loadlock chamber 12, and the wafer W is positioned based on the measurement result and then is placed onto the tray TR1. The wafer W is thus transferred to the accurate position relative to the edge ring ER, although the edge ring ER is displaced. The tray TR1 can electrostatically attract the wafer W and the edge ring ER. The edge ring ER and the wafer W placed on the tray TR1 in the loadlock chamber 12 are thus transferred into the process module 4 without any displacement from each other. When a wafer W is transferred with respect to an edge ring ER located in the process module 4, the wafer W may be displaced relative to the edge ring ER due to an error in transferring the wafer W from the loadlock chamber 12 into the process module 4. However, in the present embodiment, the wafer W is transferred with respect to the edge ring ER located in the loadlock chamber 12, eliminating such displacement of the wafer W relative to the edge ring ER due to an error in transferring the wafer W from the loadlock chamber 12 into the process module 4. More specifically, in the present embodiment, the wafer W is transferred to the accurate position relative to the edge ring ER in the loadlock chamber 12, and the wafer W and the edge ring ER are transferred from the loadlock chamber 12 into the process module 4 while being maintained at their relative positions. This enables uniform plasma processing of the wafer W in the process module 4.

The embodiments disclosed herein are illustrative in all aspects and should not be construed to be restrictive. The above embodiments may be implemented in various forms. The components in the above embodiments may be eliminated, substituted, or modified in various forms without departing from the spirit and scope of the claims.

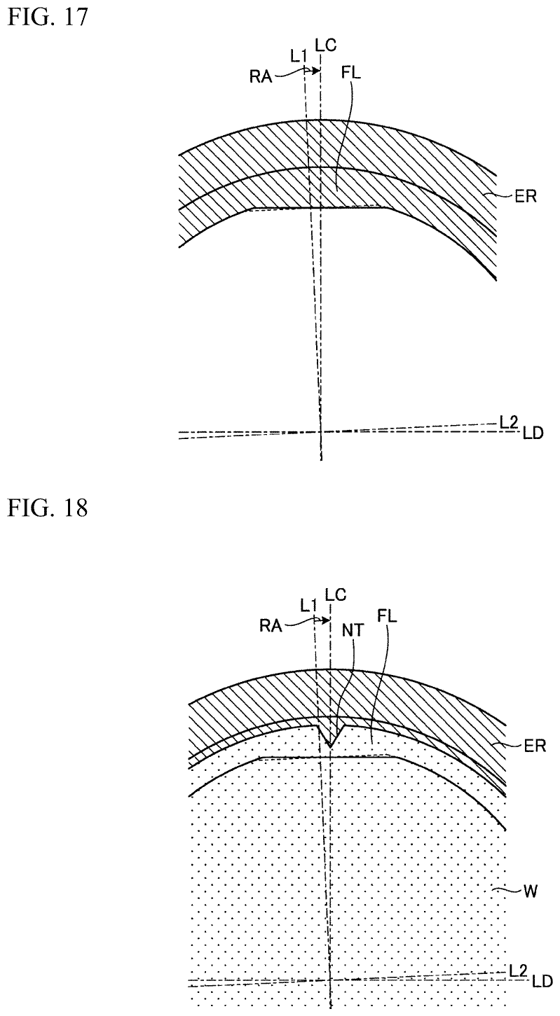

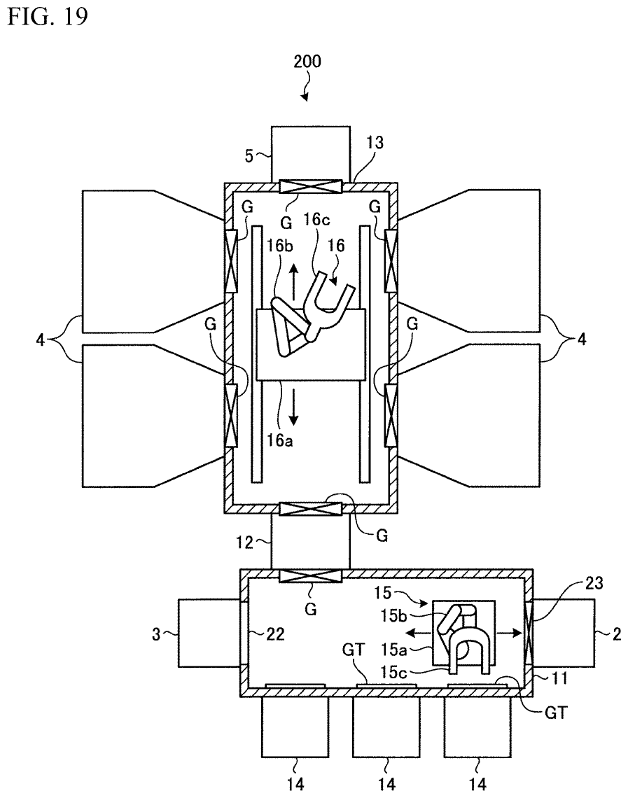

For example, the tray storage facility 5 is connected to the atmospheric transfer chamber 11 in the above embodiment. In some embodiments, the tray storage facility 5 may be connected to the vacuum transfer chamber 13 as shown in FIG. 19. FIG. 19 is a diagram of a substrate processing system with the tray storage facility 5 connected to a vacuum transfer chamber, showing its example structure. The edge-ring storage facility 2 may also be connected to the vacuum transfer chamber 13. In such cases, the second transfer mechanism 16 loads the edge ring and/or the tray into the loadlock chamber 12.

In the above embodiment, the edge ring and the wafer are placed onto the tray in the loadlock chamber 12. In some embodiments, the edge ring and the wafer may be placed onto the tray outside the loadlock chamber 12. For example, a mounting apparatus 12A separate from the loadlock chamber 12 may be connected to the atmospheric transfer chamber 11. The edge ring and the wafer may be placed onto the tray in the mounting apparatus 12A, and then the tray may be loaded into the loadlock chamber 12.

In the above embodiment, the tray TR1 is placed onto the support 204 in step S2. In some embodiments, the tray TR1 may not be placed in this step. In step S3, the first lift pin 205 may be lowered to receive the edge ring ER, and the processing in step S3 and subsequent steps may be performed with the tray TR1 supported by the first lift pin 205.

In the above embodiment, the tray is stored in the tray storage facility 5 and the edge ring is stored in the edge-ring storage facility 2, and the tray and the edge ring are separately loaded into the loadlock chamber 12. In some embodiments, a tray on which an edge ring is placed may be stored in the tray storage facility 5. In this case, the processing in steps S3 and S4 may be eliminated. The edge-ring storage facility 2, the third lift pin 207 for raising and lowering the edge ring in the mounting apparatus 12A, and the through-holes 106 for receiving the third lift pin 207 in the tray TR1 may also be eliminated.

In the above embodiment, the edge ring has its inner peripheral portion located lower than the outer peripheral portion of the wafer W. In some embodiments, the edge ring may have its inner peripheral portion not located lower than the outer peripheral portion of the wafer W. More specifically, the tray TR1 has the edge-ring support 107 lower than the substrate support 108. In some embodiments, the edge-ring support may be either higher than or flush with the substrate support.

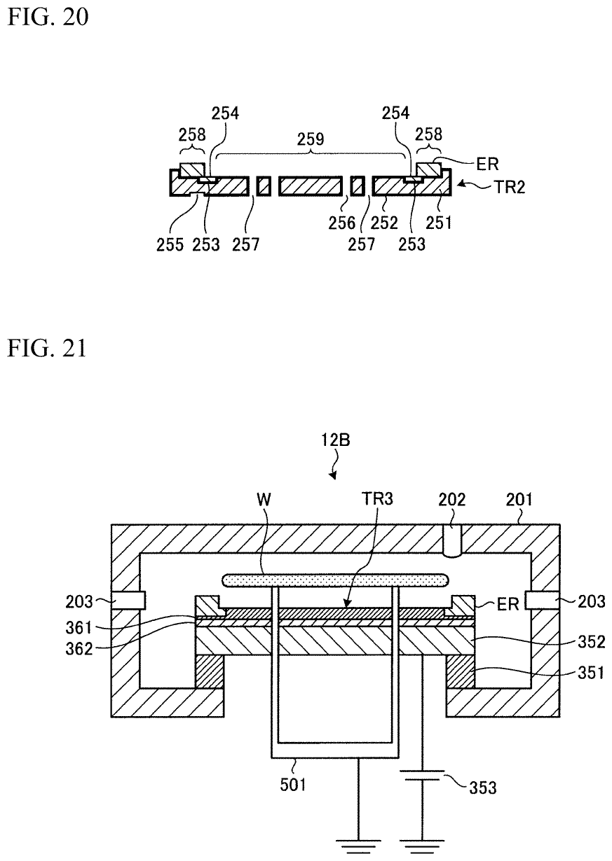

FIG. 20 is a diagram of an example tray having the edge-ring support flush with the substrate support. In FIG. 20, a tray TR2 is disk-shaped and includes a conductive tray body 251, a dielectric film 252 coating the tray body 251, an annular groove 253, a protective member 254 received in the groove 253, a lift pin contact 255, and through-holes 256 and 257. The dielectric film 252 may be located on at least the upper surface of the tray body 251. The through-holes 256 are used to supply a heat-transfer gas between the tray TR2 and the wafer W through the gas flow channel 56 (FIG. 2) in the process module 4. The through-holes 257 receive a lift pin for raising and lowering the wafer W. The tray TR2 has no through-hole for receiving a lift pin for raising and lowering the edge ring ER. In some embodiments, the tray TR2 may have such through-holes. The tray TR2 includes, on its upper surface, a substrate support 259 on which the wafer W is to be placed and an edge-ring support 258 on which the edge ring ER is to be placed. The edge-ring support 258 surrounds the substrate support 259. The substrate support 259 and the edge-ring support 258 are flush with each other.

On the tray TR2, the outer peripheral portion of the wafer W does not overlap the inner peripheral portion of the edge ring ER. This causes the dielectric film located between the wafer W and the edge ring ER to be exposed to plasma during the plasma processing. The wafer W may be contaminated by the dielectric film or by the underlying material of the tray body exposed after the dielectric film wears. The tray TR2 thus includes the protective member 254 between the substrate support 259 and the edge-ring support 258. The protective member 254 is received in the groove 253 between the substrate support 259 and the edge-ring support 258. The protective member 254 may be formed from the same material as the edge ring ER. In this case, the tray TR2 and the edge ring ER may have simpler shapes.

In the above embodiment, a DC voltage is applied to the tray body 101 using the first lift pin 205 coupled to the DC power supply 208. In some embodiments, a DC voltage may be applied to the tray body 101 without using a lift pin.

FIG. 21 is a diagram describing an example of application of a DC voltage to the tray body without using a lift pin. A mounting apparatus 12B shown in FIG. 21 serves as the loadlock chamber 12. The same components as in the mounting apparatus 12A shown in FIG. 6 are not shown or described. In FIG. 21, the mounting apparatus 12B includes a conductive support 352, an insulating support 351, a DC power supply 353, and a conductive lift pin 501. The lift pin 501 is grounded. A tray TR3 is placed onto the support 352. The edge ring ER and the wafer W are placed onto the tray TR3. The wafer W is raised or lowered using the lift pin 501 and placed onto the tray TR3. When the wafer W is raised and lowered using the lift pin 501, static electricity is eliminated from the wafer W.

The tray TR3 includes a conductive tray body 362 and a dielectric film 361 stacked on the tray body 362. Unlike the tray TR1 shown in FIG. 3, the tray TR3 includes the tray body 362 with the upper surface alone coated by the dielectric film 361 and without the lower surface coated by any dielectric film. More specifically, the conductive tray body 362 is exposed on the lower surface of the tray TR3. The DC power supply 353 applies a DC voltage to the support 352 with the tray TR3 supporting the edge ring ER and the wafer W placed on the support 352, allowing the DC voltage to be applied to the tray body 362. The tray TR3 generates a Coulomb force to electrostatically attract the wafer W to the tray TR3.

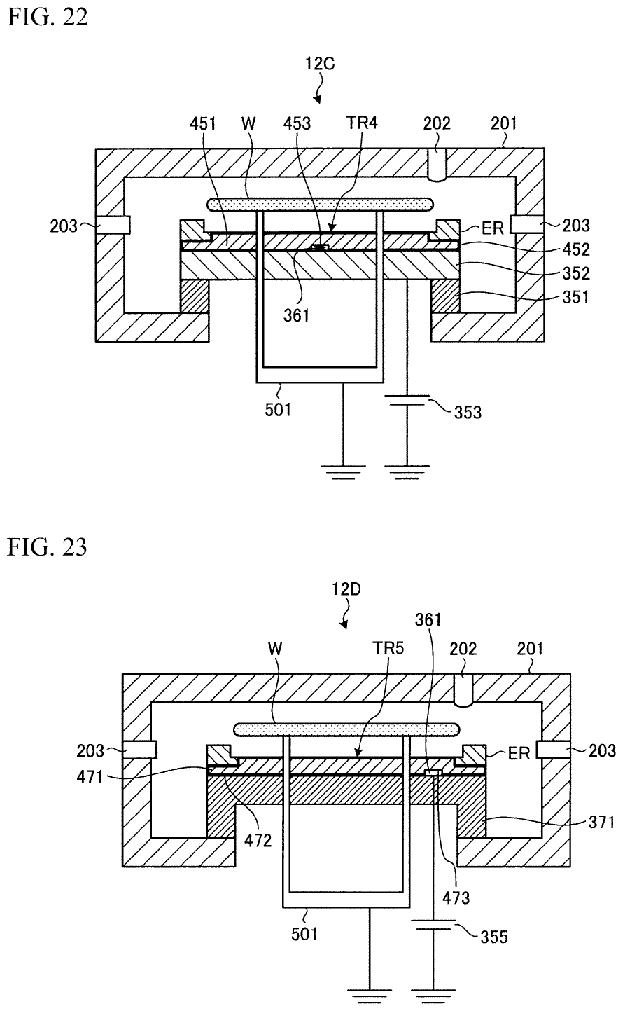

FIG. 22 is a diagram describing another example of application of a DC voltage to the tray body without using a lift pin. A mounting apparatus 12C shown in FIG. 22 serves as the loadlock chamber 12. The same components as in the mounting apparatus 12B shown in FIG. 21 are not shown and/or described. Unlike the mounting apparatus 12B shown in FIG. 21, the mounting apparatus 12C includes a conducting terminal 361 located on the upper surface of the conductive support 352. The conducting terminal 361 may be a protruding part of the conductive support 352 or may be a member separate from the support 352. For example, the conducting terminal 361 may be a spring.

A tray TR4 is placed onto the support 352. The tray TR4 includes a conductive tray body 451, a dielectric film 452 coating the tray body 451, and a DC power supply connector 453. The DC power supply connector 453 is a part of the back surface of the tray body 451 without the dielectric film 452 and to be in contact with the conducting terminal 361. The DC power supply connector 453 may be a recess shaped to receive the conducting terminal 361. Unlike the tray TR1 shown in FIG. 3, the tray TR4 includes the DC power supply connector 453. When the tray TR4 supporting the edge ring ER and the wafer W is placed onto the support 352, the conducting terminal 361 on the support 352 is coupled to the tray body 451 through the DC power supply connector 453. The DC power supply 353 applies a DC voltage to the support 352 with the tray TR4 supporting the edge ring ER and the wafer W placed on the support 352, allowing the DC voltage to be applied to the tray body 451. The tray TR4 thus generates a Coulomb force to electrostatically attract the wafer W to the tray TR4.

FIG. 23 is a diagram describing still another example of application of a DC voltage to the tray body without using a lift pin. A mounting apparatus 12D shown in FIG. 23 serves as the loadlock chamber 12. The same components as in the mounting apparatus 12C shown in FIG. 22 are not shown and/or described. Unlike the mounting apparatus 12C shown in FIG. 22, the mounting apparatus 12D includes a support 371 that is an insulating member and a DC power supply 355 that is not coupled to the support 371. The support 371 includes, on its upper surface, the conducting terminal 361 that is conductive and is directly coupled to the DC power supply 355. A tray TR5 is placed onto the support 371.

The tray TR5 includes, similarly to the tray TR4, a conductive tray body 471, a dielectric film 472 coating the tray body 471, and a DC power supply connector 473. When the tray TR5 supporting the edge ring ER and the wafer W is placed onto the support 371, the conducting terminal 361 on the support 371 comes in contact with the tray body 471 via the DC power supply connector 473. The DC power supply 355 thus applies a DC voltage to the tray body 471 with the tray TR5 supporting the edge ring ER and the wafer W placed on the support 371. The DC voltage applied to the tray body 471 generates a Coulomb force in the tray TR5, causing the tray TR5 to electrostatically attract the wafer W.

In the above embodiment, the grounded conductive lift pin eliminates static electricity from the wafer W. However, static electricity in the wafer W may be eliminated without using a lift pin.

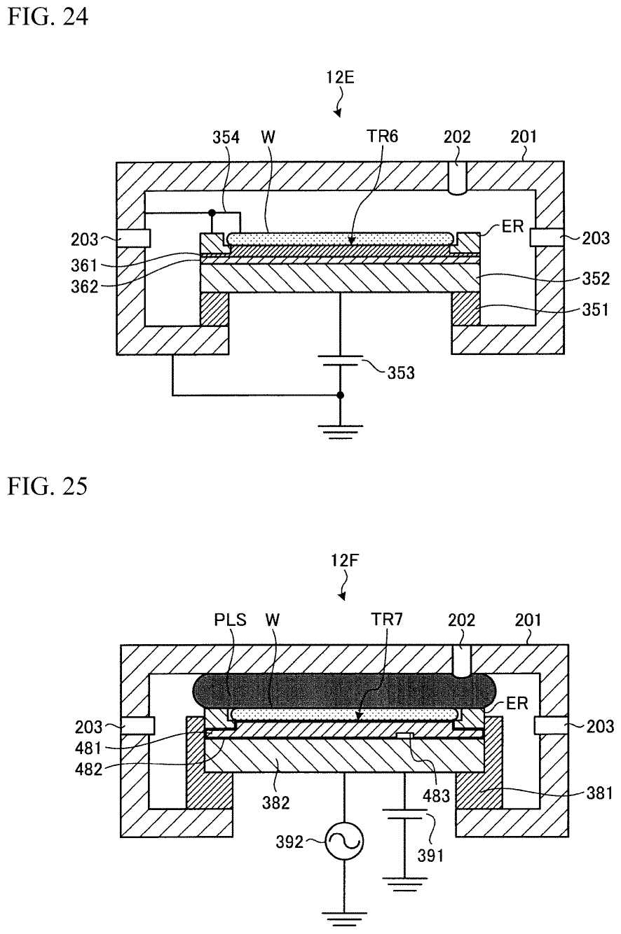

FIG. 24 is a diagram describing an example of static electricity elimination from the wafer W without using a lift pin. A mounting apparatus 12E shown in FIG. 24 serves as the loadlock chamber 12. The same components as in the mounting apparatus 12B shown in FIG. 21 are not shown and/or described. In FIG. 24, the mounting apparatus 12E includes a grounded member 354. Unlike the mounting apparatus 12B, the mounting apparatus 12E eliminates static electricity from the wafer W using the grounded member 354, instead of the grounded lift pin 501. The grounded member 354 is electrically coupled to the grounded chamber 201. The grounded member 354 can be in contact with the wafer W placed on the tray TR6. The grounded member 354 may also be in contact with the edge ring ER, in addition to the wafer W.

As shown in FIG. 24, the grounded member 354 is placed in contact with the wafer W to ground the wafer W and eliminate static electricity from the wafer W. The DC power supply 353 applies a DC voltage to the support 352 with the tray TR6 supporting the edge ring ER and the wafer W placed on the support 352. The DC voltage applied to the support 352 generates a Coulomb force in the tray TR6, causing the tray TR6 to electrostatically attract the wafer W.

FIG. 25 is a diagram describing another example of static electricity elimination from the wafer W without using a lift pin. A mounting apparatus 12F as shown in FIG. 25 serves as the loadlock chamber 12. The same components as in the mounting apparatus 12C shown in FIG. 22 are not shown and/or described. In FIG. 25, the mounting apparatus 12F includes an RF power supply 392 coupled to a conductive support 382.

When a tray TR7 supporting the edge ring ER and the wafer W is placed onto the support 382, a DC power supply 391 is coupled to a tray body 481 via a DC power supply connector 483. The DC power supply 391 coupled to the tray body 481 applies a DC voltage to the tray body 481. The RF power supply 392 applies an RF voltage for generating plasma with a frequency of 30 to 150 MHz to the support 382. Such a high RF voltage applied to the support 382 can generate plasma PLS in the chamber 201. The edge ring ER and the wafer W are grounded through the plasma PLS generated in the chamber 201. The DC voltage applied to the tray body 481 generates a Coulomb force in the tray TR7, causing the tray TR7 to electrostatically attract the wafer W.

In the above embodiment, the tray serves as a monopolar ESC. In some embodiments, the tray may serve as a bipolar ESC.

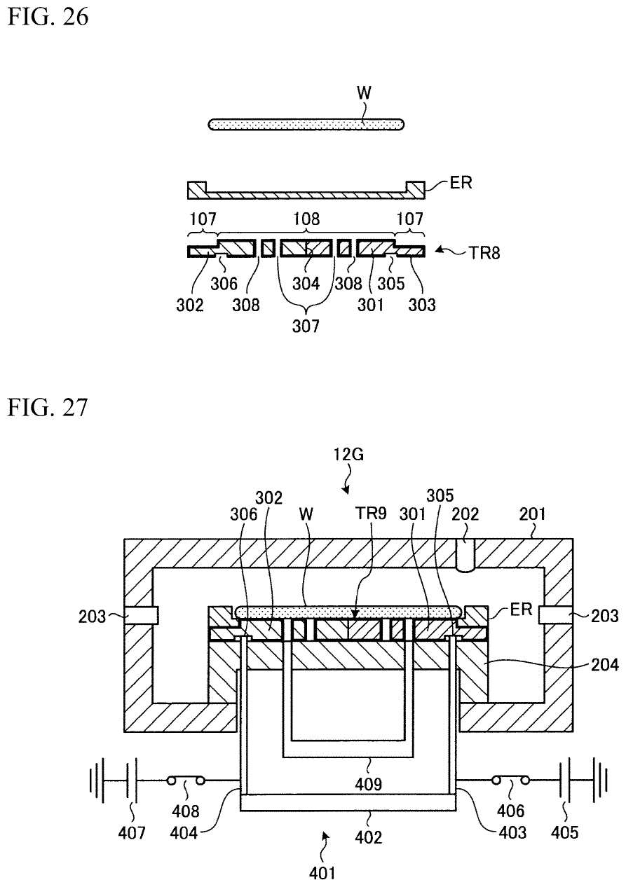

FIG. 26 is a diagram of an example tray serving as a bipolar ESC. In FIG. 26, a tray TR8 is disk-shaped and includes a conductive first tray body 302, a conductive second tray body 301, a dielectric film 303 coating the first tray body 302 and the second tray body 301, an insulating layer 304, lift pin contacts 305 and 306, and through-holes 307 and 308. Unlike the tray TR1, the tray TR8 includes two bodies, or the first tray body 302 and the second tray body 301, divided by the insulating layer 304 and each including a lift pin contact. The insulating layer 304 electrically divides the first tray body 302 and the second tray body 301 in the horizontal direction. The through-holes 307 are used to supply a heat-transfer gas between the tray TR8 and the wafer W through the gas flow channel 56 (FIG. 2) in the process module 4. The through-holes 308 receive a lift pin.

FIG. 27 is a diagram of an example mounting apparatus for mounting a tray TR9. A mounting apparatus 12G shown in FIG. 27 serves as the loadlock chamber 12. Unlike the mounting apparatus 12A shown in FIG. 6, the mounting apparatus 12G shown in FIG. 27 includes a first lift pin 401, an insulating second lift pin 409, a first DC power supply 407, a second DC power supply 405, and switches 406 and 408. The first lift pin 401 includes a conductive first pin 404, a conductive second pin 403, and an insulating support 402 that connects the first pin 404 and the second pin 403. The mounting apparatus 12G further includes a first lift mechanism (not shown) for raising and lowering the first lift pin 401 and a second lift mechanism (not shown) for raising and lowering the second lift pin 409 independently of the first lift pin 401. The first pin 404 is coupled to the first DC power supply 407 via the switch 408, and the second pin 403 is coupled to the second DC power supply 405 via the switch 406.

As shown in FIG. 27, a tray TR9 supporting the wafer W and the edge ring ER is placed onto the support 204. The first pin 404 and the second pin 403 are in contact with lift pin contacts 305 and 306. The switch 408 is turned on to couple the first pin 404 to the first DC power supply 407, allowing the first DC power supply 407 to apply a positive DC voltage to the first pin 404. The first pin 404 receives a positive DC voltage from the first DC power supply 407, which is then applied to the first tray body 302 through the first pin 404 and the lift pin contact 306. The switch 406 is turned on to couple the second pin 403 to the second DC power supply 405, allowing the second DC power supply 405 to apply a negative DC voltage to the second pin 403. The second pin 403 receives a negative DC voltage from the second DC power supply 405, which is then applied to the second tray body 301 through the second pin 403 and the lift pin contact 305. The DC voltage applied to the first tray body 302 and the second tray body 301 generates a Coulomb force in the tray TR9, causing the tray TR9 to electrostatically attract the wafer W. The edge ring ER formed from, for example, a conductive material such as Si or SiC is also electrostatically attracted to the tray TR9.

In the above embodiment, the aligner 3 rotates and horizontally positions the wafer W in step S6. However, the first transfer mechanism 15 may be controlled to horizontally position the wafer W based on the horizontal position information HPI about the edge ring ER. More specifically, to horizontally position the wafer W, the first transfer mechanism 15 may transfer the wafer W to above the support 204 to allow the wafer W to be concentric with the edge ring ER based on the horizontal position information HPI about the edge ring ER.

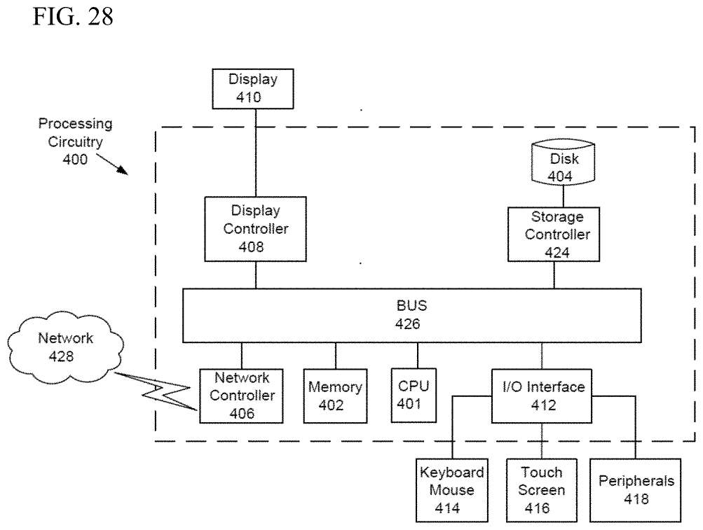

The operations of the individual components in the substrate processing system 100 or 200 and the entire operation (sequence) of the substrate processing system 100 or 200 are controlled by a controller. The controller may be a microcomputer, or processing circuitry like that shown in FIG. 28. FIG. 28 is a block diagram of processing circuitry for performing computer-based operations described herein. FIG. 28 illustrates processing circuitry 400 that may be used to control any computer-based and cloud-based control processes, descriptions or blocks in flowcharts can be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art. The various elements, features, and processes described herein may be used independently of one another or may be combined in various ways. All possible combinations and sub-combinations are intended to fall within the scope of this disclosure.

In FIG. 28, the processing circuitry 400 includes a CPU 401 which performs one or more of the control processes described above/below. The process data and instructions may be stored in memory 402. These processes and instructions may also be stored on a storage medium disk 404 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the processing circuitry 400 communicates, such as a server or computer. The processes may also be stored in network based storage, cloud-based storage or other remote accessible storage and executable by processing circuitry 400.

Further, the claimed advancements may be provided as a utility application, background daemon, or component of an operating system, or combination thereof, executing in conjunction with CPU 401 and an operating system such as Microsoft Windows, UNIX, Solaris, LINUX, Apple MAC-OS and other systems known to those skilled in the art.

The hardware elements in order to achieve the processing circuitry 400 may be realized by various circuitry elements. Further, each of the functions of the above described embodiments may be implemented by circuitry, which includes one or more processing circuits. A processing circuit includes a particularly programmed processor, for example, processor (CPU) 401, as shown in FIG. 28. A processing circuit also includes devices such as an application specific integrated circuit (ASIC) and conventional circuit components arranged to perform the recited functions.

In FIG. 28, the processing circuitry 400 includes a CPU 401 which performs the processes described above. The processing circuitry 400 may be a general-purpose computer or a particular, special-purpose machine. In one embodiment, the processing circuitry 400 becomes a particular, special-purpose machine when the processor 401 is programmed to perform edge-ring, tray, and wafer transfer and placement by controlling the transfer mechanism and sensors as discussed above. The processing circuitry 400 may be in or locally communicable to substrate processing apparatus 200. In some embodiments, processing circuitry 400 may be remote from substrate processing apparatus 200, providing processing instructions to substrate processing apparatus 200 via network 428.

Alternatively, or additionally, the CPU 401 may be implemented on an FPGA, ASIC, PLD or using discrete logic circuits, as one of ordinary skill in the art would recognize. Further, CPU 401 may be implemented as multiple processors cooperatively working in parallel to perform the instructions of the inventive processes described above.

The processing circuitry 400 in FIG. 28 also includes a network controller 406, such as an Intel Ethernet PRO network interface card from Intel Corporation of America, for interfacing with network 428. As can be appreciated, the network 428 can be a public network, such as the Internet, or a private network such as an LAN or WAN network, or any combination thereof and can also include PSTN or ISDN sub-networks. The network 428 can also be wired, such as an Ethernet network, or can be wireless such as a cellular network including EDGE, 3G and 4G wireless cellular systems. The wireless network can also be Wi-Fi, Bluetooth, or any other wireless form of communication that is known.

The processing circuitry 400 further includes a display controller 408, such as a graphics card or graphics adaptor for interfacing with display 410, such as a monitor. A general purpose I/O interface 412 interfaces with a keyboard and/or mouse 414 as well as a touch screen panel 416 on or separate from display 410. General purpose I/O interface also connects to a variety of peripherals 418 including printers and scanners.

The general-purpose storage controller 424 connects the storage medium disk 404 with communication bus 426, which may be an ISA, EISA, VESA, PCI, or similar, for interconnecting all of the components of the processing circuitry 400. A description of the general features and functionality of the display 410, keyboard and/or mouse 414, as well as the display controller 408, storage controller 424, network controller 406, and general purpose I/O interface 412 is omitted herein for brevity as these features are known.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset.

The functions and features described herein may also be executed by various distributed components of a system. For example, one or more processors may execute these system functions, wherein the processors are distributed across multiple components communicating in a network. The distributed components may include one or more client and server machines, which may share processing, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

The embodiments disclosed herein are illustrative in all aspects and should not be construed to be restrictive. The above embodiments may be implemented in various forms. The components in the above embodiments may be eliminated, substituted, or modified in various forms without departing from the spirit and scope of the claims. For example, although etching is described as an example of substrate processing in the above embodiments, the substrate processing performed with the technique according to the present disclosure is not limited to etching. For example, the technique according to the present disclosure is applicable to film deposition as one example of substrate processing by modifying the degree of vacuum in the process space PS and selecting a process gas suitable for film deposition.

### REFERENCE SIGNS LIST

100, 200 Substrate processing system
2 Edge-ring storage facility
3 Aligner
4 Process module
5 Tray storage facility
11 Atmospheric transfer chamber
12 Loadlock chamber
13 Vacuum transfer chamber
14 Front-opening unified pod (FOUP)
15 First transfer mechanism
16 Second transfer mechanism
400 Processing circuitry
401 CPU
402 Memory
404 Storage Medium
406 Network controller
408 Display controller
410 Display
412 I/O interface
414 Keyboard and/or mouse
416 Touch screen panel
418 Peripherals
424 Storage controller
426 Communications bus
428 Network

1. A transfer method for a substrate processing system, the transfer method comprising:
loading a tray on which a semiconductor substrate and an edge ring are placeable into a mounting chamber that includes a support;
measuring a position of the edge ring placed on the tray and obtaining position information about the edge ring;
positioning the semiconductor substrate based on the position information about the edge ring;
after the positioning, placing the semiconductor substrate onto the tray and
removing the tray on which the semiconductor substrate and the edge ring are placed from the mounting chamber.

2. The transfer method according to claim 1, wherein
the tray includes a conductive tray body and a dielectric film disposed on at least an upper surface of the conductive tray body, and
the transfer method further comprises, between the placing and the removing, electrostatically attracting the semiconductor substrate to the tray by applying a voltage to the conductive tray body.

3. The transfer method according to claim 2, wherein
in the electrostatically attracting, the applying includes applying the voltage through a first lift pin used in placing the tray onto the support.

4. The transfer method according to claim 3, wherein
the electrostatically attracting the semiconductor substrate includes contacting the first lift pin with a back surface of the tray body.

5. The transfer method according to claim 2, wherein
the electrostatically attracting the semiconductor substrate includes generating plasma using a radio frequency power supply electrically coupled to the support.

6. The transfer method according to claim 2, wherein
the electrostatically attracting includes applying the voltage through a conducting terminal located on the support.

7. The transfer method according to claim 1, wherein
the mounting chamber is connected to an atmospheric transfer chamber including a first transfer assembly.

8. The transfer method according to claim 1, wherein
the position information includes rotation angle information about the edge ring and horizontal position information about the edge ring.

9. The transfer method according to claim 8, further comprising:
transferring the semiconductor substrate to a position above the support with a first transfer assembly,
wherein the positioning the semiconductor substrate is performed before the transferring the semiconductor substrate, and includes rotating the semiconductor substrate based on the rotation angle information.

10. The transfer method according to claim 8, further comprising:
transferring the semiconductor substrate to a position above the support with a first transfer assembly,
wherein the positioning the semiconductor substrate is performed before the transferring the semiconductor substrate, and includes horizontally positioning the semiconductor substrate based on the horizontal position information.

11. The transfer method according to claim 8, further comprising:
transferring the semiconductor substrate to a position above the support with a first transfer assembly based on the horizontal position information.

12. The transfer method according to claim 7, wherein
the placing the semiconductor substrate includes raising a second lift pin to separate the semiconductor substrate from the first transfer assembly, and
lowering the second lift pin to place the semiconductor substrate onto the tray.

13. The transfer method according to claim 12, wherein
the second lift pin is grounded, and the raising the second lift pin includes eliminating static electricity from the semiconductor substrate.

14. The transfer method according to claim 7, wherein
the loading the tray includes loading the tray into the mounting chamber using the first transfer assembly.

15. The transfer method according to claim 7, wherein
the mounting chamber is a loadlock chamber connected to the atmospheric transfer chamber and to a vacuum transfer chamber including a second transfer assembly.

16. The transfer method according to claim 15, wherein
the loading the tray includes loading the tray into the mounting chamber using the second transfer mechanism.

17. The transfer method according to claim 1, wherein
the loading the tray includes loading the tray on which the edge ring is placed into the mounting chamber.

18. The transfer method according to claim 1, further comprising:
placing the edge ring onto the tray, wherein the placing occurs between the loading the tray and the measuring the position.

19. A transfer apparatus in a substrate processing system, the transfer apparatus comprising:
a tray into which a semiconductor substrate and an edge ring are placeable into;
a mounting chamber that includes a support;
a transfer assembly configured to transport the tray into the mounting chamber;
a sensor configured to measure a position of the edge ring placed on the tray and obtain position information about the edge ring; and
control circuitry configured to
receive the position information,
control the transfer assembly to
position the semiconductor substrate based on the position information,
place the semiconductor substrate onto the tray after the positioning, and
remove the tray on which the semiconductor substrate and the edge ring are placed from the mounting chamber.
